(19) United States
(12) Patent Application Publication
(10) Pub. No.: US 2025/0360532 A1
(43) Pub. Date: Nov. 27, 2025

(54) COATING FILM FORMING APPARATUS, COATING FILM FORMING METHOD, AND STORAGE MEDIUM

(71) Applicant: Tokyo Electron Limited, Tokyo (JP)

(72) Inventor: Tetsuo FUKUOKA, Kumamoto (JP)

(21) Appl. No.: 18/832,385

(22) PCT Filed: Jan. 11, 2023
(86) PCT No.: PCT/JP2023/000457

§ 371 Date: Feb. 12, 2025

(30) Foreign Application Priority Data
Jan. 24, 2022 (JP) 2022-008914

(51) Int. Cl. B05C 11/06; B05C 5/02; B05C 13/00

(52) U.S. Cl. CPC B05C 11/06; B05C 5/0204; B05C 13/00

(57) ABSTRACT

A coating film forming apparatus of the present disclosure includes: a rotation holder configured to hold and rotate a substrate; a coating liquid nozzle configured to discharge a coating liquid to a first position of a peripheral edge portion of the substrate which is rotating and form a coating film of an annular shape along a circumference of the substrate; and a gas nozzle configured to discharge gas to a second position on a downstream side of a rotational direction of the substrate near a rotational center of the substrate rather than to the first position on the substrate which is rotating, and provided to shape the coating film by a flow of the gas toward a peripheral end of the substrate from the second position.

This is a National Phase Application filed under 35 U.S.C. 371 as a national stage of PCT/JP2023/000457, filed Jan. 11, 2023, an application claiming the benefit of Japanese Application No. 2022-008914, filed Jan. 24, 2022, the content of each of which is hereby incorporated by reference in its entirety.

### TECHNICAL FIELD

The present disclosure relates to a coating film forming apparatus, a coating film forming method, and a non-transitory computer-readable storage medium.

### BACKGROUND

In a manufacturing process of semiconductor devices, a coating film is sometimes formed by supplying a coating liquid to a peripheral edge portion of a semiconductor wafer (hereinafter referred to as a “wafer”). Patent Document 1 discloses forming a coating film on a peripheral edge portion of a rotating wafer by moving a nozzle so that a position to which a processing liquid (coating liquid) is supplied moves between an outer periphery and the peripheral edge portion of the wafer.

### PRIOR ART DOCUMENT

### Patent Document

Patent Document 1: International Laid-Open Publication No. 2018-207672

The present disclosure provides a technique for suppressing an inner peripheral end of a coating film from rising when forming the coating film of an annular shape along the circumference of a substrate on a peripheral edge portion of the substrate.

### SUMMARY

A coating film forming apparatus of the present disclosure includes: a rotation holder configured to hold and rotate a substrate; a coating liquid nozzle configured to discharge a coating liquid to a first position of a peripheral edge portion of the substrate which is rotating and form a coating film of an annular shape along a circumference of the substrate; and a gas nozzle configured to discharge gas to a second position on a downstream side of a rotational direction of the substrate near a rotational center of the substrate rather than to the first position on the substrate which is rotating, and provided to shape the coating film by a flow of the gas toward a peripheral end of the substrate from the second position.

According to the present disclosure, it is possible to suppress an inner peripheral end of a coating film from rising when forming the coating film of an annular shape along the circumference of a substrate on a peripheral edge portion of the substrate.

### BRIEF DESCRIPTION OF DRAWINGS

FIG. 1 is a longitudinal cross-sectional side view of a coating film forming apparatus according to an embodiment of the present disclosure.

FIG. 2 is a transverse cross-sectional plan view of the coating film forming apparatus.

FIG. 3 is a plan view illustrating a gas nozzle and a coating liquid nozzle provided in the coating film forming apparatus.

FIG. 4 is a side view illustrating the gas nozzle.

FIG. 5 is a plan view illustrating a gas nozzle and a coating liquid nozzle provided in the coating film forming apparatus.

FIG. 6 is a side view illustrating an operation of the coating film forming apparatus.

FIG. 7 is a side view illustrating an operation of the coating film forming apparatus.

FIG. 8 is a side view illustrating an operation of the coating film forming apparatus.

FIG. 9 is a longitudinal cross-sectional side view of a wafer, which illustrates a state of a coating film.

FIG. 10 is a longitudinal cross-sectional side view of the wafer, which illustrates a state of the coating film.

FIG. 11 is a longitudinal cross-sectional side view of the wafer, which illustrates the state of the coating film.

FIG. 12 is a longitudinal cross-sectional side view of the wafer, which illustrates a state of the coating film.

FIG. 13 is a plan view illustrating another configuration example of the coating film forming apparatus.

FIG. 14 is an explanatory diagram illustrating processing in another configuration example.

FIG. 15 is a longitudinal cross-sectional side view illustrating another configuration example of the gas nozzle.

FIG. 16 is a plan view of a wafer for explaining a positional relationship between the gas nozzle and the wafer.

FIG. 17 is a plan view illustrating yet another configuration example of the gas nozzle.

FIG. 18 is a longitudinal cross-sectional side view of the gas nozzle.

FIG. 19 is a graph illustrating results of an evaluation experiment.

FIG. 20 is a graph illustrating results of an evaluation experiment.

FIG. 21 is a graph illustrating results of an evaluation experiment.

FIG. 22 is a graph illustrating results of an evaluation experiment.

FIG. 23 is a graph illustrating results of an evaluation experiment.

### DETAILED DESCRIPTION

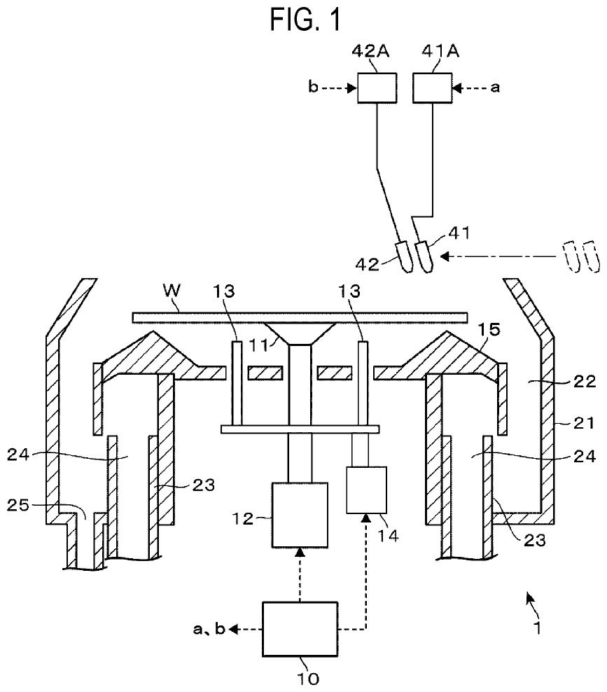

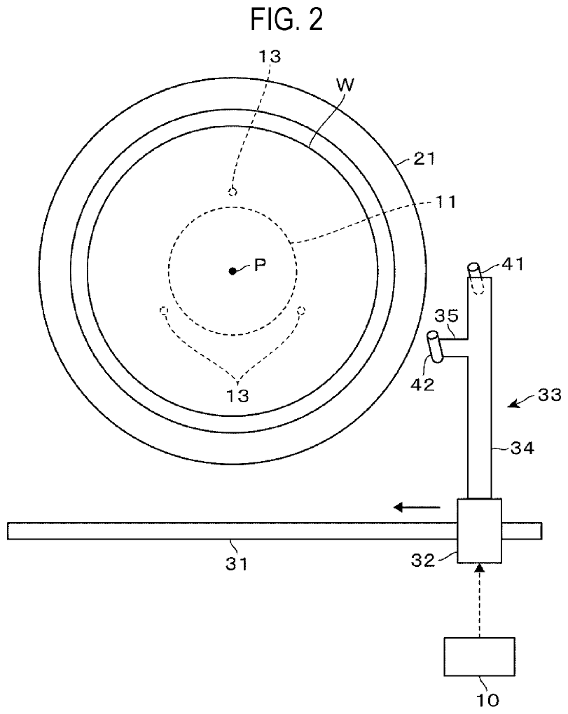

A coating film forming apparatus 1 according to an embodiment of the present disclosure will be described with reference to a longitudinal cross-sectional side view of FIG. 1 and a transverse cross-sectional plan view of FIG. 2. The coating film forming apparatus 1 rotates a wafer W, which is a circular substrate, and discharges a coating liquid from a nozzle to a peripheral edge portion of a surface of the wafer W. The coating liquid flows toward a peripheral end of the wafer W from the discharged position, thereby forming an annular coating film M along the circumference of the wafer W. As will be described later in detail, when forming the coating film M in this way, the coating film forming apparatus 1 supplies, to the wafer W, gas for preventing formation of a hump M1, which is a protrusion at an inner peripheral end of the coating film M. In this example, a diameter of the wafer W is 300 mm, and the gas supplied to the wafer W is air.

The coating film forming apparatus 1 includes a spin chuck 11, a rotation mechanism 12, pins 13, a lifting mechanism 14, a guide ring 15, and a cup 21. The spin chuck 11, which is a rotation holder, holds the wafer W horizontally by vacuum-suctioning the center of a back surface of the wafer W. The spin chuck 11 is connected to the rotation mechanism 12 including a motor. The rotation mechanism 12 rotates the spin chuck 11 around a vertical axis thereof at a rotational speed according to a control signal output from a controller 10 which will be described later. A center P of the wafer W is placed on the spin chuck 11 so as to be aligned with a rotational center of the spin chuck 11 in a plan view. Thus, the center P is also a rotational center of the wafer W. A rotational direction of the wafer W is a clockwise direction in a plan view.

Three pins 13 for supporting the wafer W are provided (only two pins are shown in FIG. 1) so as to surround the spin chuck 11 in a plan view and are configured to be raised and lowered by the lifting mechanism 14. The wafer W is delivered between a transfer mechanism (not illustrated) for the wafer W and the spin chuck 11 by the pins 13. Further, the guide ring 15 having a mountain-shaped longitudinal cross section is provided below the spin chuck 11. An outer peripheral edge of the guide ring 15 is bent and extends downward. The guide ring 15 serves to guide liquid overflowing from the wafer W to the bottom of the cup 21.

Next, the cup 21 will be described. The cup 21 is circular and is provided to surround the guide ring 15, the spin chuck 11, and the wafer W placed on the spin chuck 11 and to suppress the coating liquid from scattering. An upper side of the cup 21 is open so that the wafer W is delivered via such an opening. A gap 22 serving as a liquid-gas discharge path is formed between a side circumferential surface of the cup 21 and the outer peripheral edge of the guide ring 15. An upright exhaust pipe 23 is provided below the cup 21, and an exhaust port 24 is open at an upper end of the exhaust pipe 23. An interior of the cup 21 is constantly exhausted via the exhaust port 24 while the wafer W is being processed. Further, a drain port 25 is open at the bottom of the cup 21.

The coating film forming apparatus 1 also includes a guide 31, a movement mechanism 32, a support body 33, a coating liquid nozzle 41, and a gas nozzle 42. The guide 31 is provided on a rear side of the cup 21 so as to extend horizontally to the left and right. The movement mechanism 32 is movable in a direction in which the guide 31 extends. The support body 33 includes an arm portion 34 extending forward from the movement mechanism 32 and a sub-arm portion 35 connected to the arm portion 34, and is raised and lowered by the movement mechanism 32. Here, left and right sides in the following description are a left side and a right side when viewed from the rear toward the front.

The arm portion 34 and the sub-arm portion 35 will now be described in more detail. The sub-arm portion 35 is formed by being branched from the arm portion 34 extending forward. The sub-arm portion 35 extends to the left side. The coating liquid nozzle 41 and the gas nozzle 42 are provided at a tip end of the arm portion 34 and a tip end of the sub-arm portion 35, respectively. Therefore, the coating liquid nozzle 41 and the gas nozzle 42 are connected to the movement mechanism 32 which is common to the nozzles 41 and 42 via the support body 33. The coating liquid nozzle 41 and the gas nozzle 42 may be horizontally moved to the left and right sides and may be raised and lowered by the movement mechanism 32.

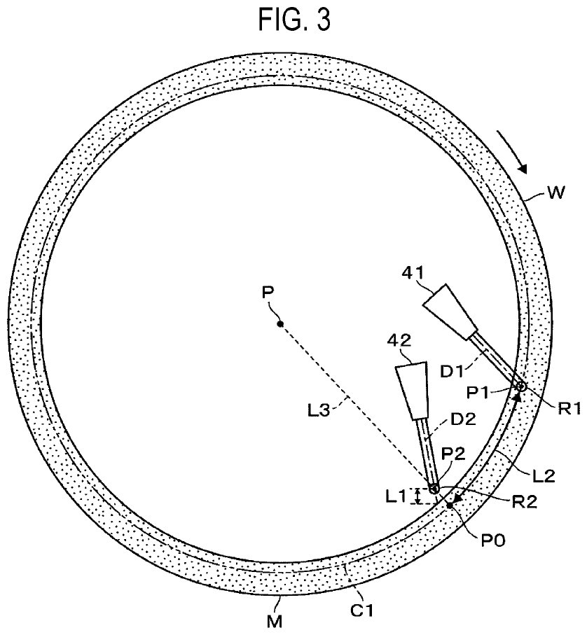

The coating liquid nozzle 41 and the gas nozzle 42 are configured to be movable between standby positions outside the cup 21 (i.e., outside the wafer W loaded in the cup 21) and processing positions above a peripheral edge portion of the wafer W in a plan view. FIG. 2 shows a state in which the coating liquid nozzle 41 and the gas nozzle 42 are located at the standby positions. A plan view of FIG. 3 shows a state in which the coating liquid nozzle 41 and the gas nozzle 42 are located at the processing positions. At the processing positions, the coating liquid nozzle 41 and the gas nozzle 42 discharge the coating liquid and air toward the peripheral edge portion of the wafer W, respectively. The standby position and the processing position of the coating liquid nozzle 41 refer to a first standby position and a first processing position, respectively, and the standby position and the processing position of the gas nozzle 42 refer to a second standby position and a second processing position, respectively.

The coating liquid nozzle 41 is configured, for example, as a cylindrical body with an outer circumferential wall that tapers toward a tip end thereof and includes a circular discharge port on a tip end surface thereof. The coating liquid nozzle 41 is connected to a coating liquid supplier 41A via a pipe. The coating liquid supplier 41A includes a valve, a storage in which the coating liquid is stored, and a pump. The coating liquid supplier 41A forcibly feeds the coating liquid from the storage toward the coating liquid nozzle 41 and causes the coating liquid nozzle 41 to discharge the coating liquid.

An orientation of the coating liquid nozzle 41 will now be described. In order to form the coating film M having a desired width by preventing the coating liquid discharged onto the rotating wafer W from moving toward the center P of the wafer W, the coating liquid nozzle 41 discharges the coating liquid downward from a center side of the wafer W toward a peripheral end side of the wafer W. In other words, the coating liquid is discharged in an oblique direction with respect to a vertical plane and a horizontal plane.

In FIG. 3, the rotational direction of the wafer W is indicated by an arrow. The coating liquid nozzle 41 discharges the coating liquid in a direction that follows the rotational direction of the wafer W in a plan view. By discharging the coating liquid in this way, the coating liquid is prevented from bouncing and scattering on the wafer W, thereby increasing the uniformity of a film thickness of the coating film. The direction that follows the rotational direction will be described in more detail when describing the gas nozzle 42. In FIG. 3, a region projected onto the wafer W by extending the discharge port of the coating liquid nozzle 41 at the processing position in a discharge direction of the coating liquid is denoted by a projection region R1. The center of the projection region R1 is denoted by P1. The projection region R1 corresponds to a first position on the wafer W at which the coating liquid is discharged. Further, the discharge direction of the coating liquid from the coating liquid nozzle 41 is indicated by a dash-dotted line as D1 in the figure. Since this dash-dotted line is expressed as a straight line passing through the center of the discharge port of the coating liquid nozzle 41, the dash-dotted line is drawn so as to pass through the center P1 of the projection region R1.

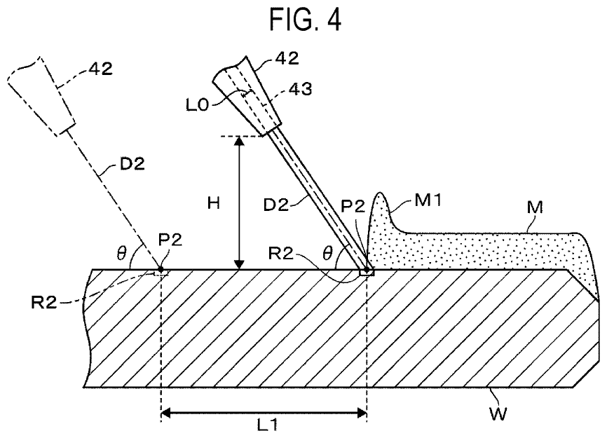

Here, the hump M1, which is a protrusion of the coating film M mentioned above, will now be described with reference to FIG. 4, which is a longitudinal cross-sectional side view of the wafer W. Most of the coating liquid discharged toward the projection region R1 flows toward the peripheral end of the wafer W by the discharge of the coating liquid from the center side toward the peripheral edge portion side and by a centrifugal force of the wafer W. However, some of the coating liquid moves from the projection region R1 to a position near the center P of the wafer W outside the projection region R1 due to pressure generated when the coating liquid collides with the wafer W. At the position near the center P, it is difficult to supply the coating liquid compared to a region from the projection region R1 to the peripheral end of the wafer W, and the flow of the coating liquid is gentle. As a result, the coating liquid dries relatively quickly. Thus, since the supply of the coating liquid to the position near the center P and the drying of the coating liquid proceed together, the hump M1 described above may be formed at the position. From another perspective, it can be said that the drying of the coating liquid progresses quickly in the hump M1. Since the hump M1 is formed as described above, the hump M1 has, for example, an annular shape along the circumference of the wafer W.

The gas nozzle 42 discharges air so that a flow of the air is formed from the inner peripheral end of the coating film M toward an outer edge (i.e., peripheral end of the wafer W). In addition, the gas nozzle 42 is configured to collapse the hump M1 prior to solidification by air pressure and push the coating liquid constituting the hump M1 toward the outer edge side of the coating film M. In this way, the gas nozzle 42 shapes the coating film M so that the hump M1 is eliminated. In order to certainly obtain this effect, in this example, a duration in which the air is discharged by the gas nozzle 42 is set to overlap a duration in which the coating liquid is discharged by the coating liquid nozzle 41, for the purpose of discharging the air to the hump M1 before fluidity disappears.

Hereinafter, the gas nozzle 42 will be described. The gas nozzle 42 is configured, for example, as a cylindrical body with an outer circumferential wall that tapers toward a tip end thereof, and a circular discharge port 43 is open at a tip end surface of the gas nozzle 42. Further, the gas nozzle 42 is connected to a gas supplier 42A via a pipe. The gas supplier 42A includes a valve, a flow rate adjustment mechanism, an air source, and the like. By opening and closing the valve, air is supplied from the air source to the gas nozzle 42. A flow rate of the air supplied to the gas nozzle 42 (i.e., a flow rate of the air discharged by the gas nozzle 42) is adjusted by the flow rate adjustment mechanism to a predetermined flow rate. A temperature of the air supplied from the gas supplier 42A to the gas nozzle 42 is, for example, 16 degrees C. to 24 degrees C.

Hereinafter, the arrangement of the gas nozzle 42 at the processing position will be described with reference to FIGS. 3 and 4. As described above, the gas nozzle 42 is configured to provide the effect of the air pressure directed toward the peripheral end of the wafer W with respect to the inner peripheral end of the coating film M. In order to ensure this effect, the gas nozzle 42 discharges air downward from the center side of the wafer W toward the peripheral end side of the wafer W. That is, the air is discharged in an oblique direction with respect to the vertical plane and the horizontal plane. In the figure, a region projected onto the wafer W by extending the discharge port of the gas nozzle 42 at the processing position in a discharge direction of the gas is denoted by a projection region R2, and the center of the projection region R2 is indicated by P2. The projection region R2 corresponds to a second position on the wafer W at which the gas is discharged.

Further, a discharge direction of the gas by the gas nozzle 42 is indicated by a dash-dotted line as D2 in the figure. This dash-dotted line is expressed as a straight line passing through the center of the discharge port 43 of the gas nozzle 42. Therefore, the dash-dotted line is drawn so as to pass through the center P2 of the projection region R2. An angle between the discharge direction D2 of the gas and the surface of the wafer W in a side view is shown in FIG. 4 as a side-view nozzle angle θ. Since the wafer W is placed on the spin chuck 11 so that the surface thereof is horizontal, the side-view nozzle angle θ is also an angle between the horizontal plane and the discharge direction D2 of the gas.

In a case where the flow rate of the air discharged by the gas nozzle 42 is constant, the force for pressing the hump M1 toward the peripheral end of the wafer W may be strengthened as the side-view nozzle angle θ becomes smaller. However, when the side-view nozzle angle θ is too small, there is a greater risk that the gas nozzle 42 and the wafer W will come into contact with each other. From that point of view, it is desirable that the side-view nozzle angle θ is 20 degrees or more as described above. Further, as will be described later in evaluation experiments, it has been confirmed that the hump M1 could be removed by setting the side-view nozzle angle θ to 30 degrees or 60 degrees. Therefore, the side-view nozzle angle θ is desirably 20 degrees to 60 degrees, more desirably, 30 degrees to 60 degrees.

Further, in the air discharge direction in a plan view, a distance between the center P2 of the projection region R2 of the gas nozzle 42 and the inner peripheral end of the coating film M is defined as a film separation distance L1. The film separation distance L1 may be as small as possible, from the viewpoint of sufficiently increasing the pressure of the air acting on the coating film M. As will be described later in the evaluation experiments, the film separation distance L1 is desirably 0 mm or more and smaller than 5 mm, more desirably, 0 mm to 3 mm. In FIG. 4, the gas nozzle 42 in the case where the processing position is set so that the film separation distance L1 is 0 mm is denoted by a solid line, and the gas nozzle 42 in the case where the processing position is set so that the film separation distance L1 is larger than 0 mm is denoted by a dash-double-dotted line.

The position of the inner peripheral end of the coating film M on the wafer W may be detected by previously conducting, for example, an experiment, and the position of the projection region R2 of the gas nozzle 42 may be set based on the position of the inner peripheral end and the film separation distance L1. Due to the spread of the coating liquid discharged to the projection region R1 by the coating liquid nozzle 41, for example, the inner peripheral end of the coating film M, rather than the projection region R1, may be located slightly closer to the center P of the wafer W (see FIG. 3). In that case, when comparing the position of the center P1 of the projection region R1 with the position of the center P2 of the projection region R2 in a radial direction of the wafer W, the projection region R2 is located near the center P of the wafer W even if the film separation distance L1 is 0 mm, for example.

Next, a positional relationship between the projection region R1 and the projection region R2 in the rotational direction of the wafer W will be described. As shown in FIG. 3, the projection region R2 is located on a downstream side of the projection region R1 in the rotational direction. The downstream side in the rotational direction will now be supplementarily described. When viewed in the rotational direction of the wafer W, two arc areas are located in the rotational direction between the projection regions R1 and R2. A side of the shorter arc area of the two arc areas is the downstream side in the rotational direction. More specifically, as shown in FIG. 3, when viewed in the rotational direction of the wafer W from the projection region R1 as a starting point, the projection region R2 is on the downstream side in the rotational direction, and when viewed in the rotational direction of the wafer W from the projection region R2 as a starting point, the projection region R1 is on the downstream side in the rotational direction. Although the positional relationship between the projection regions R1 and R2 differs depending on the starting points, lengths of the above-mentioned arc areas between the projection regions R1 and R2 are compared, and based on the comparison result, the projection region R1 is set as the starting point.

As described above, drying progresses relatively quickly in the hump M1. When the hump M1 solidifies as the drying progresses, it becomes impossible to collapse and remove the hump M1 by the air pressure. That is, in order to remove the hump M1, it is required that the hump M1, to which the air is supplied, has just been discharged onto the wafer W and is made of a coating liquid having sufficient fluidity. Therefore, the positional relationship is set such that the projection region R2 is located on the downstream side in the rotational direction with respect to the projection region R1.

In order to more reliably obtain the effect of air, it is desirable that the distance between the projection regions R1 and R2 is closer. However, the air discharged to the projection region R2 diffuses the surface of the wafer W due to impact caused by collision with the projection region R2. When the distance between the projection regions R1 and R2 is too small, a liquid flow of the coating liquid discharged by the coating liquid nozzle 41 may fluctuate by the air diffusing on the surface of the wafer W. This may deteriorate uniformity of the film thickness of the coating film M. Therefore, from the viewpoint of more reliably suppressing the fluctuation of the liquid flow of the coating liquid while obtaining a high pressing effect on the coating film M by the air, a separation distance L2 between the projection regions R1 and R2 in the rotational direction of the wafer W may be set to an appropriate value, specifically, for example, from 30 mm to 100 mm.

A description will be supplementarily given regarding the above-described separation distance L2 between the projection regions R1 and R2 in the rotational direction. As shown in FIG. 3, a virtual straight line L3 is drawn from the center P of the wafer W toward the peripheral end of the wafer W by passing through the center P2 of the projection region R2. On the other hand, a virtual circle C1 that is centered on the center P of the wafer W and passes through the center P1 of the projection region R1 is set, and an intersection of the circle C1 and the straight line L3 is indicated by P0. A length of an arc between the center P1 of the projection region R1 and the intersection P0 in the circle C1 is the separation distance L2. As described above, the positions of the coating liquid nozzle 41 and the gas nozzle 42 in the rotational direction of the wafer W are different from each other. In FIG. 1, for the sake of convenience in description, the positions of these nozzles in the rotational direction are the same and are arranged in the radial direction of the wafer W.

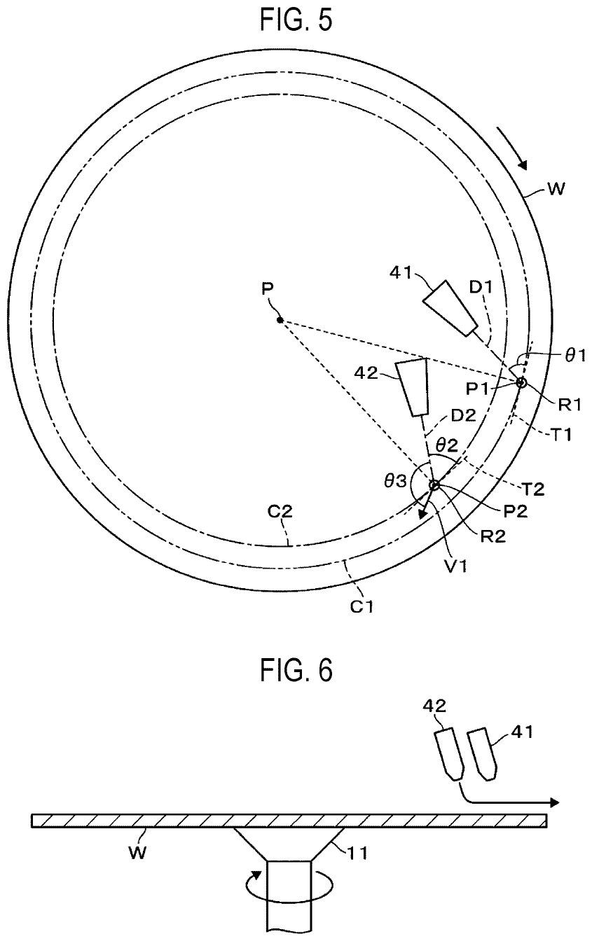

A description will be continued below with reference to a plan view of the wafer W of FIG. 5. In a plan view, the discharge direction D2 of the gas by the gas nozzle 42 is set to a direction following the rotational direction of the wafer W, i.e., a direction that does not reverse the rotation of the wafer W. A supplementary description of the rotational direction will now be given. The center P2 of the projection region R2 from which air is discharged moves in a uniform circular motion with the rotation of the wafer W. When an angle θ3 between a velocity vector V1 starting from the center P2 and the discharge direction D2 of the gas in a plan view is an obtuse angle, the gas is discharged to follow the rotational direction of the wafer W (see FIG. 5). In this way, the discharge direction D2 follows the rotational direction of the wafer W, which makes it possible to prevent the air discharged to the projection region R2 from bouncing by the rotation of the wafer W and scattering around the wafer W, and from disrupting the liquid flow supplied to the wafer W and flowing through the peripheral end of the wafer W. As a result, the uniformity of the film thickness of the coating film M may be improved.

Here, a virtual circle C2 that passes through the center P2 of the projection region R2 of the gas nozzle 42 and is centered on the center P of the wafer W is set. This circle C2 is a trajectory drawn by the center P2 of the projection region R2 with the rotation of the wafer W. A tangent line T2 is drawn at the center P2 to the circle C2. The gas nozzle 42 is arranged so that the discharge direction D2 of the gas follows the rotational direction as described above. In this case, when an angle between the tangent line T2 and the discharge direction D2 of the gas in a plan view refers to a plane gas-discharge angle θ2, the plane gas-discharge angle θ2 is, for example, 30 degrees to 90 degrees.

Further, a tangent line T1 at the center P1 is drawn with respect to the circle C1 passing through the center P1 of the projection region R1 of the coating liquid nozzle 41 described above. An angle between the tangent line T1 and the discharge direction D1 of the coating liquid in a plan view refers to a plane liquid-discharge angle θ1. In this example, the plane liquid-discharge angle θ1 and the plane gas-discharge angle θ2 are equal in magnitude to each other. For example, the plane liquid-discharge angle θ1 and the plane gas-discharge angle θ2 may be 60 degrees. The discharge direction D1 of the coating liquid and the discharge direction D2 of the gas in a plan view may be parallel to each other. By making the discharge directions D1 and D2 parallel in this way, the gas flow by the gas nozzle 42 may be prevented from being close to the liquid flow by the coating liquid nozzle 41, and the above-mentioned liquid flow may be suppressed more reliably from fluctuating.

A height distance between a bottom of the gas nozzle 42 and the surface of the wafer W refers to a nozzle height distance H (see FIG. 4). When the nozzle height distance H is too large, the air pressure acting on the hump M1 may be decreased. When the nozzle height distance H is too small, the gas nozzle 42 and the wafer W may come into contact with each other. From this viewpoint and results of evaluation experiments described later, the nozzle height distance H may be set to be smaller than 10 mm, more desirably, 3 mm to 5 mm.

Further, from the viewpoint of sufficiently increasing the air pressure acting on the hump M1 and from the results of the evaluation experiments described later, the flow rate of the air discharged by the gas nozzle 42 may be set to be greater than 10 L/minute, for example, 20 L/minutes or more. Further, from the viewpoint of sufficiently increasing the air pressure acting on the hump M1 and preventing pressure loss from becoming too large due to the discharge port 43 being too small, the diameter L0 of the discharge port 43 may be set to, for example, 0.5 mm to 2 mm.

As illustrated in FIG. 1, the coating film forming apparatus 1 includes a controller 10. The controller 10 is constituted with a computer and includes a program. The program incorporates a group of steps for executing a series of operations of the coating film forming apparatus 1, which will be described later. Further, according to the program, the controller 10 outputs control signals to each part of the coating film forming apparatus 1 to control the operation of each part. Specifically, the operations, such as the rotational speed of the spin chuck 11 by the rotation mechanism 12, the lifting and lowering of the pins 13 by the lifting mechanism 14, the supply of the coating liquid to the coating liquid nozzle 41 by the coating liquid supplier 41A, the supply of the air to the gas nozzle 42 by the gas supplier 42A, and the movement of each nozzle by the movement mechanism 32, are controlled by the above control signals. The above program is stored in a non-transitory computer-readable storage medium such as a compact disc, a hard disk, or a DVD, and installed in the controller 10.

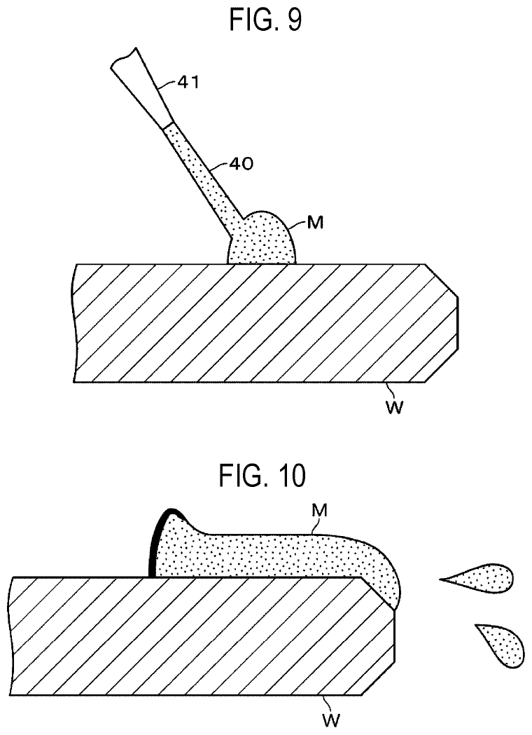

Next, a processing operation perform on the wafer W by the coating film forming apparatus 1 will be described with reference to FIGS. 6 to 8, which illustrate side views of the wafer W, the coating liquid nozzle 41, and the gas nozzle 42. Similarly to FIG. 1, in FIGS. 6 to 8, the coating liquid nozzle 41 and the gas nozzle 42 are illustrated at the same position in the rotational direction of the wafer W and are arranged in the radial direction of the wafer W. In addition, changes in the state of the coating film M that are estimated to occur on the surface of the wafer W during the processing of the wafer W will be described with reference to FIGS. 9 to 12. FIGS. 9 to 12 illustrate longitudinal cross sections in the radial direction of the wafer W with respect to the coating film M. In FIGS. 10 and 11, portions at which drying have progressed to a relatively large extent on the surface of the coating film M are indicated by thick lines.

First, the wafer W is transferred above the cup 21 by a transfer mechanism (not illustrated) when the coating liquid nozzle 41 and the gas nozzle 42 are in a standby state at the standby positions outside the cup 21 described above. The wafer W is placed and held on the spin chuck 11 by the pins 13. Then, the wafer W rotates at a rotational speed lower than, for example, 250 revolutions per minute (rpm), specifically, for example, at 100 rpm. Subsequently, when the coating liquid nozzle 41 and the gas nozzle 42 are moved to respective processing positions by the movement mechanism 32, the gas nozzle 42 starts to discharge air, and an air flow is formed toward the peripheral end of the wafer W in the peripheral edge portion of the surface of the wafer W (FIG. 6).

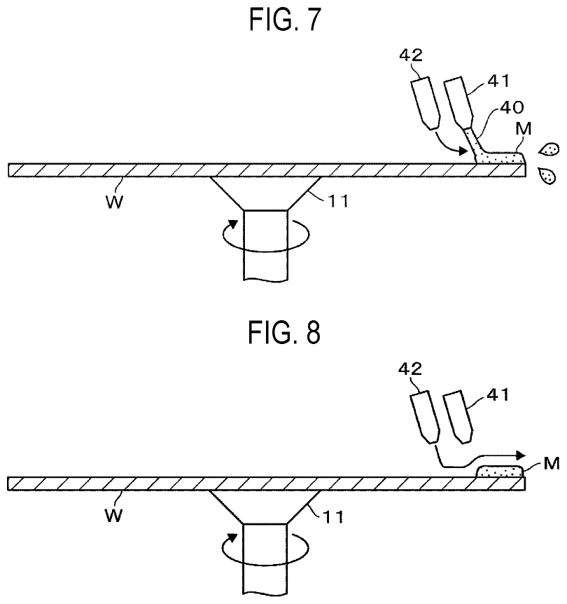

By rotating the wafer W one or more times, for example, multiple times, from the start of air discharge, the air is supplied to the entire peripheral edge portion of the wafer W, and the temperature of each part of the peripheral edge portion becomes uniform. Subsequently, the coating liquid is discharged by the coating liquid nozzle 41 to the projection region R1 of the wafer W described above (FIG. 9). This coating liquid flows toward the peripheral end of the wafer W by virtue of the centrifugal force generated with the rotation of the wafer W and momentum of the discharge by the coating liquid nozzle 41, so that the coating film M is formed (FIG. 7) and the hump M1 is formed at the inner peripheral end of the coating film M. The liquid flow of the coating liquid discharged by the coating liquid nozzle 41 is indicated by reference numeral 40 in each figure. As mentioned above, it is difficult for the coating liquid to move near the center P of the wafer W. Therefore, it is difficult for the coating liquid to flow on a side oriented to the center P of the wafer W (i.e., an inner peripheral end surface of the coating film M), and drying progresses relatively quickly in the hump M1 (FIG. 10).

With the rotation of the wafer W, the hump M1 moves near a position at which the air is discharged (near the projection region R2 described above), so that the hump M1 is exposed to an air flow, and air pressure toward the peripheral end acts on the hump M1. Due to this air pressure, the side surface of the hump M1, which has been dried, cracks vertically, and an upper side of the hump M1 moves to be misaligned with a lower side of the hump M1 toward the peripheral end side of the wafer W. The upper side of the hump M1 that moves toward the peripheral end side of the wafer W moves to sink downward from an original height because the fluidity of the coating film M is ensured when the air is discharged (FIG. 11).

As described above, the hump M1 collapses to be separated into upper and lower portions due to the air pressure. The separated portions form respective protrusions at different positions in the radial direction of the wafer W. However, heights of the protrusions are lower than that of the original hump M1. Therefore, the height of the coating film M in the radial direction becomes uniform.

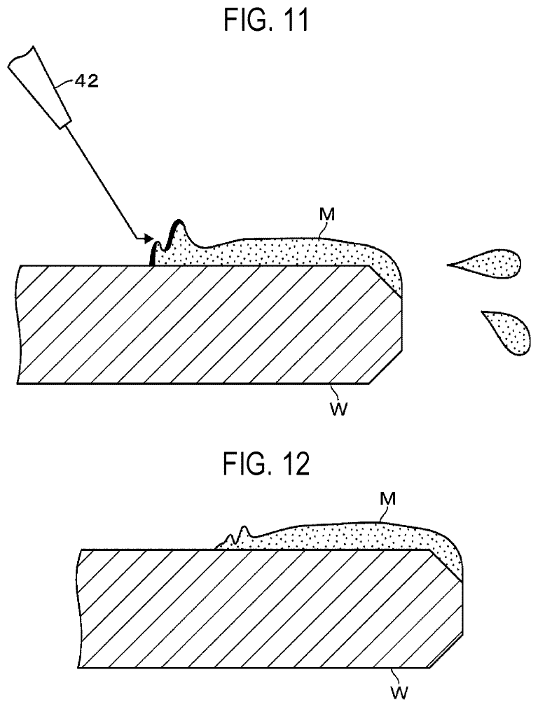

An area in which the height of the coating film M in the radial direction becomes uniform in this way moves away from a position at which the air is discharged by the rotation of the wafer W, and drying and solidification progress in each portion of the area (FIG. 12). By continuing to rotate the wafer W and discharge the coating liquid and air onto the wafer W, the formation of the coating film M described above and the removal of the hump M1 (specifically, the collapse of the hump M1) that occurs together with the formation of the coating film M are performed in parallel at different positions in the rotational direction of the wafer W.

Then, when the wafer W rotates once from the start of discharging the coating liquid, the coating liquid is supplied over the entire circumference of the wafer W. After the annular coating film M that covers the entire peripheral edge portion of the wafer W is formed, the discharge of the coating liquid by the coating liquid nozzle 41 is stopped (FIG. 8). After a region of the wafer W that has been located in the projection region R1 when the discharging of the coating liquid is stopped moves to the vicinity of the projection region R2 and is affected by the air, that is, after the hump M1 is eliminated from the entire circumference of the wafer W, the discharge of the air by the gas nozzle 42 is stopped. When the coating film M is dried and has a desired thickness, the rotation of the wafer W is stopped. Thereafter, the wafer W is delivered to the transfer mechanism (not illustrated) in a reverse order of the delivery of the wafer W to the spin chuck 11 and is unloaded from the coating film forming apparatus 1.

In this way, according to the coating film forming apparatus 1, since the formation of the hump M1 is suppressed, the uniformity of the height of the coating film M in the radial direction may be increased. Therefore, it is possible to suppress the occurrence of issues in the processing of the wafer W in a post-process after forming the coating film M, due to the formation of the hump M1. As a result, a decrease in the yield of semiconductor products manufactured from the wafer W may be prevented.

The issues of the above-mentioned post-process will now be described by taking a specific example. The type of the coating film M is not particularly limited. In a specific example, the coating film M is assumed to be a film formed on the wafer W on which an underlying layer film, and a resist film on which a pattern is formed are sequentially formed upward. More specifically, no resist film is formed on the peripheral edge portion of the wafer W, and the coating film M is formed to cover the underlying layer film in the peripheral edge portion and surround the resist film. The coating film M serves as a protective film that prevents a peripheral edge portion of the underlying layer film from being etched upon transferring a pattern to the underlying layer film by dry-etching the underlying layer film along the pattern of the resist film.

Processing conditions for etching are set such that the coating film M is also etched together with the underlying layer film and the coating film M is completely removed at the end of the etching. However, when the hump M1 is formed, it is considered that the hump M1 will become a residue on the underlying layer film after the etching. In other words, since a portion forming the hump M1 in the coating film M is thicker in film thickness than other portions, the portion may not be completely eliminated by the etching and may remain. It is considered that the residue of the coating film M becomes particles and adheres to the pattern formed on the underlying layer film, which causes the decrease in yield described above. However, according to the coating film forming apparatus 1, since the coating film M may be formed so as not to form the hump M1, it is possible to prevent the yield from decreasing due to the residue.

However, in the above processing example, by starting the supply of the air to the wafer W by the gas nozzle 42 before the coating liquid nozzle 41 starts discharging the coating liquid, the temperature of each portion in the peripheral edge portion of the wafer W is uniform. For this reason, after the coating liquid is supplied, since the drying of the coating liquid is performed with high uniformity at each portion of the peripheral edge portion, film thickness is desirably suppressed from varying. In addition, as described above, the reason that the rotational speed of the wafer W is set to be lower than 250 rpm when discharging the coating liquid and air onto the wafer W is that, when the rotational speed is too large, the drying of the hump M1 proceeds quickly, which will be described later in the evaluation experiments. In other words, such rotational speed is desirably used because it is possible to highly and reliably eliminate the hump M1 by suppressing the drying of the hump M1.

In the above processing example, the coating liquid has been described as being applied only once on the peripheral edge portion of the wafer W, that is, as not being repeatedly applied. However, the coating liquid may be repeatedly applied on the peripheral edge portion of the wafer W. Even in such a case, the hump M1 may be eliminated.

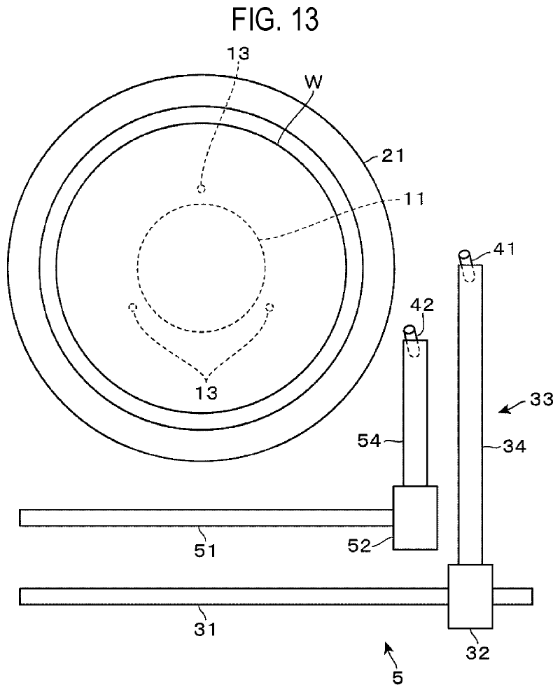

Next, a coating film forming apparatus 5, which is a modification of the coating film forming apparatus 1, will be described with reference to FIG. 13, focusing on differences from the coating film forming apparatus 1. In the coating film forming apparatus 5, the support body 33 provided with the coating liquid nozzle 41 is not provided with the sub-arm portion 35 and the gas nozzle 42, and the support body 33 is constituted with only the arm portion 34. The coating film forming apparatus 5 is provided with a guide 51, a movement mechanism 52, and an arm 54 that are configured similarly to the guide 31, the movement mechanism 32, and the arm portion 34, respectively. The gas nozzle 42 is provided at a tip end of the arm 54. The gas nozzle 42 may move horizontally in a left-right direction and move vertically by the movement mechanism. Therefore, in the coating film forming apparatus 5, the coating liquid nozzle 41 and the gas nozzle 42 are connected to the different movement mechanisms 32 and 52, respectively, and may be moved independently of each other. In the coating film forming apparatus 5, the movement mechanism 32 corresponds to a first movement mechanism, and the movement mechanism 52 corresponds to a second movement mechanism.

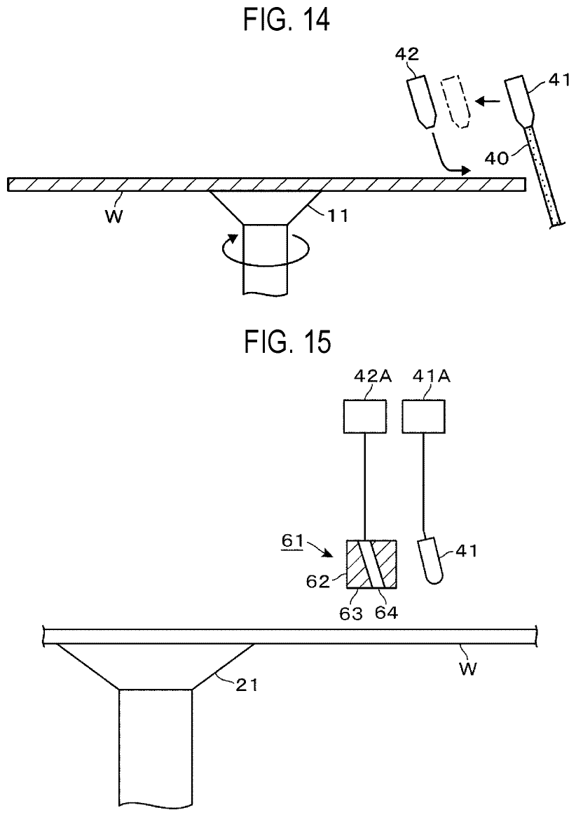

A processing example of the wafer W by the coating film forming apparatus 5 will now be described with reference to FIG. 14. In this processing example, the coating liquid nozzle 41 discharges a coating liquid at a position other than the position described as the processing position in the coating film forming apparatus 1. First, similarly to the coating film forming apparatus 1, air is discharged onto the rotating wafer W by the gas nozzle 42 at the processing position. Subsequently, the coating liquid nozzle 41 starts discharging the coating liquid. However, the position of the coating liquid nozzle 41 at the start of discharge is a position horizontally separated from the previously-described processing position, as illustrated by a solid line in FIG. 14, and the coating liquid is discharged outward of the wafer W. The processing position is indicated by a dash-dotted line in the figure.

Then, the coating liquid nozzle 41, which has discharged the coating liquid, is moved horizontally toward the processing position. Along with this movement, the projection region R1 of the coating liquid nozzle 41 onto the wafer W moves from the peripheral end of the wafer W toward the center P of the wafer W in the radial direction of the wafer W. Then, after the coating liquid nozzle 41 moves to the processing position, the coating liquid nozzle 41 is stopped. When a coating film R is formed on the entire circumference of the wafer W, the discharge of the coating liquid is stopped. When forming a film using the coating liquid nozzle 41 as described above, the gas nozzle 42 may remain stationary while discharging the coating liquid, or may have a movement duration.

Even if the coating liquid nozzle 41 is constituted with a device which is movable independently of the gas nozzle 42 as in the coating film forming apparatus 5, the coating liquid nozzle 41 may remain stationary at the processing position while discharging the coating liquid as described with reference to FIGS. 6 to 8. However, in that case, the coating film forming apparatus 5 is advantageous in having the same configuration as the coating film forming apparatus 1 in terms of simplification.

The gas nozzle is not limited to having the circular discharge port 43 like the gas nozzle 42 described above. FIG. 15 illustrates an example in which a gas nozzle 61 is provided instead of the gas nozzle 42 in the coating film forming apparatus 1. The gas nozzle 61 is formed in a rectangular block shape. An air flow path 62 extending from above to below is formed inside the gas nozzle 61. The flow path 62 is formed obliquely from the center P of the wafer W toward the peripheral end side of the wafer W in the gas nozzle 61 at the processing position. A bottom surface 63 of the gas nozzle 61 faces the wafer W. A discharge port 64 forming a downstream end of the flow path 62 is open in the bottom surface 63. The discharge port 64 is an arc-shaped slit in a plan view.

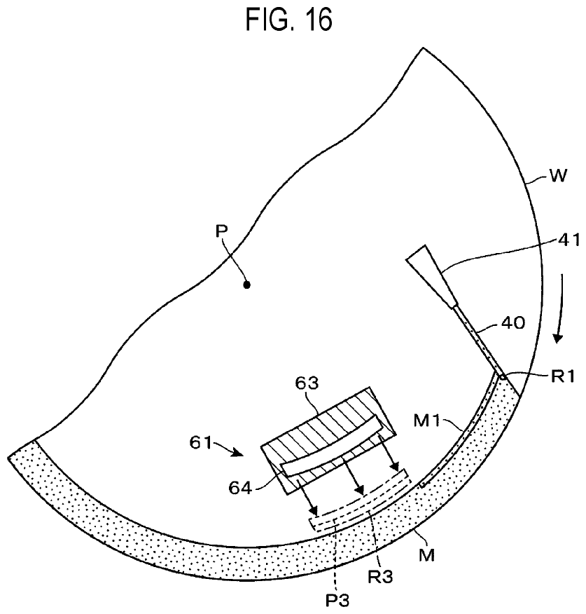

A positional relationship between the gas nozzle 61 disposed at the processing position and the coating film M formed on the wafer W will be described below with reference to FIG. 16, which is a plan view of the wafer W. Since the discharge port 64 has an arc shape, a projection region R3 of the discharge port 64 onto the wafer W in an air discharge direction also has an arc shape. The arc of the projection region R3 follows an inner peripheral end of the coating film M, as illustrated in FIG. 16. That is, the above-mentioned discharge port 64 is formed to follow the inner peripheral end of the coating film M. By forming the discharge port 64 in this way, a range in which the hump M1 may be pressed with air in the wafer W becomes relatively large, so that the hump M1 may be eliminated highly reliably.

In FIG. 16, a width center P3 of the projection region R3 is indicated by a dotted line. The film separation distance L1 has been described in FIGS. 3 and 4. When the discharge port 64 is formed along the inner peripheral end of the coating film M as illustrated in FIG. 16, a distance in the air discharge direction in a plan view between each portion of the width center P3 of the projection region R3 in a length direction and the coating film M may be identical to the film separation distance L1.

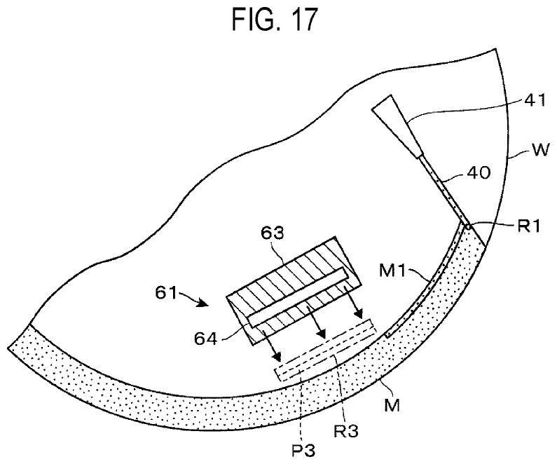

In FIG. 17, an example is illustrated in which the discharge port 64 is formed with a straight slit instead of a curved shape along the inner peripheral end of the coating film M. When the discharge port 64 is formed in this way, a distance between each portion of the width center P3 of the projection region R3 in the length direction and the inner peripheral end of the coating film M in the air discharge direction in a plan view is different from each other. In the case where the distance between each portion of the width center P3 and the inner peripheral end of the coating film M is different from each other, when a portion of each portion falls within the range described as the film separation distance L1, a sufficient air pressure may desirably act on the hump M1. When the entire width center P3 in the length direction falls within the range described as the film separation distance L1, the air pressure may desirably be applied to the hump M1 more reliably.

The discharge port 64 may be a curved slit that does not follow the inner peripheral end of the coating film M. In this case, the positional relationship between the inner peripheral end of the coating film M and the width center P3 of the projection region R3 may be similar to the positional relationship between the inner peripheral end of the coating film M and the width center P3 of the projection region R3 when the discharge port 64 is a linear slit as illustrated in FIG. 17. That is, it is desirable that at least a portion of the width center P3 falls within the range described as the film separation distance L1.

While each gas nozzle has been described as having a configuration in which air is discharged from the center side of the wafer W toward the peripheral end side, the air may be discharged vertically downward. That is, the nozzle angle θ illustrated in FIG. 4 in a side view may be 90 degrees. Since the interior of the cup 21 is evacuated while the wafer W is being processed, the air discharged in the vertical direction flows along the surface of the wafer W toward the outer periphery of the wafer W. Therefore, as described above, the pressure of the air may act on the hump M1. However, in order to obtain the effect of air more reliably, it is desirable that the gas nozzle is configured to discharge the air from the center side of the wafer W toward the peripheral end side of the wafer W.

Further, in the embodiment described above, a discharge duration in which the coating liquid is discharged onto the wafer W and a discharge duration in which the air is discharged onto the wafer W overlap. The air is supplied while the hump M1 has fluidity. Thus, the air may start to be discharged after the coating liquid has been discharged depending on properties of the coating liquid used. In other words, the discharge duration of the coating liquid and the discharge duration of the air may not overlap. However, in order to more reliably eliminate the hump M1, it is desirable that the discharge durations overlap and it is more desirable to make a timing of starting the discharge of the gas earlier than a timing of starting the discharge of the coating liquid, after the discharge durations overlap.

Further, the gas discharged onto the wafer W is not limited to air. For example, an inert gas such as a nitrogen gas may be used. Further, the gas supplier 42A may be provided with a heater or a cooling mechanism, and may supply gas having a temperature higher or lower than normal temperature to the gas nozzle 42.

The embodiments disclosed herein should be considered to be exemplary in all aspects and not limitative. The above-described embodiments may be omitted, replaced, modified, and combined in various ways without departing from the scope and spirit of the appended claims.

### EVALUATION EXPERIMENTS

Next, Evaluation Experiments relating to this technology will be described.

### Evaluation Experiment 1

In Evaluation Experiments 1-1 to 1-5, the coating film M was formed on the wafer W. An experiment device having the same configuration as the coating film forming apparatus 1 was used for this processing. Therefore, the gas nozzle 42 described above is used as a gas nozzle. Further, a film thickness of the coating film M at each position in a radial direction was measured using a stylus type step gauge with respect to the wafer W on which the coating film was formed. This measurement will now be described in more detail. A tip end (bottom) of a needle that is movable vertically was brought into contact with the surface of the wafer W. Then, the needle was moved in the radial direction of the wafer W toward the peripheral end of the wafer W. The film thickness was measured by detecting the vertical movement of the needle while the wafer W moves in the radial direction. Evaluation Experiments 1-1 to 1-5 differ in combinations of the rotational speed of the wafer W during the discharge of the coating liquid and air, the flow rate of the air discharged by the gas nozzle 42, and a timing at which the air discharge is started.

In Evaluation Experiment 1-1, the processing was performed by discharging the coating liquid and air onto the wafer W at the rotational speed of the wafer W of 100 rpm. The discharge of the air was started several seconds after the coating film M was formed on the entire circumference of the wafer W. The flow rate of the discharged air was 40 L/min. This flow rate corresponds to an air speed of 7 m/sec.

In Evaluation Experiment 1-2, the processing was performed by discharging the coating liquid and air onto the wafer W at the rotational speed of the wafer W of 100 rpm. As in the embodiment, a timing at which the air starts to be discharged was earlier than a timing at which the coating liquid starts to be discharged. The flow rate of the air discharged by the gas nozzle 42 was 40 L/min, which is the same as in Evaluation Experiment 1-1.

In Evaluation Experiment 1-3, the flow rate of the air was 30 L/min. This flow rate corresponds to an air speed of 10 m/sec. In Evaluation Experiment 1-4, the flow rate of the air was 20 L/min. This flow rate corresponds to an air speed of 7 m/sec. Evaluation Experiments 1-3 and 1-4 had the same processing conditions as Evaluation Experiment 1-2, except for different flow rates of the air. In Evaluation Experiment 1-5, the processing was performed in the same manner as Evaluation Experiment 1-3, except that the rotational speed of the wafer W was 250 rpm. In Evaluation Experiments 1-1 to 1-5, the film separation distance L1 described in FIGS. 3 and 4 was set to 0 mm.

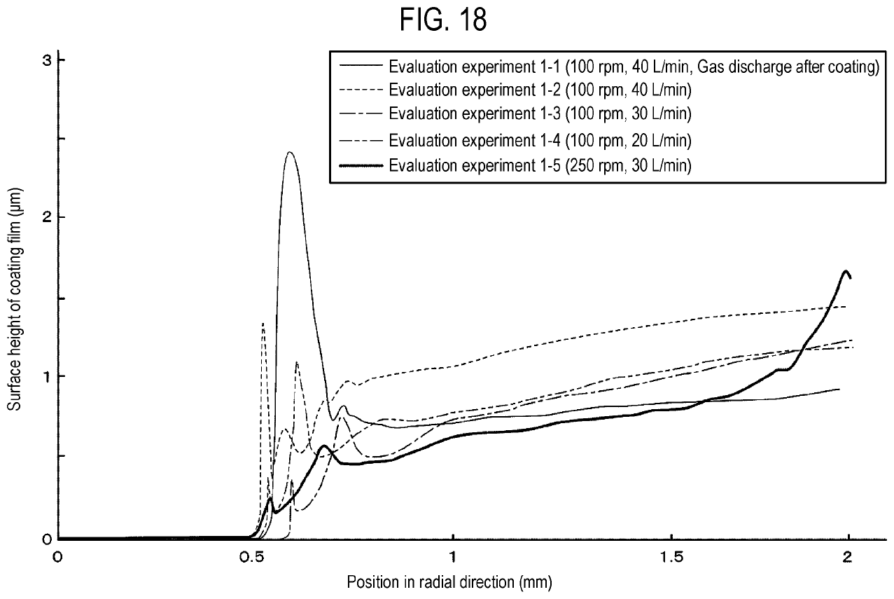

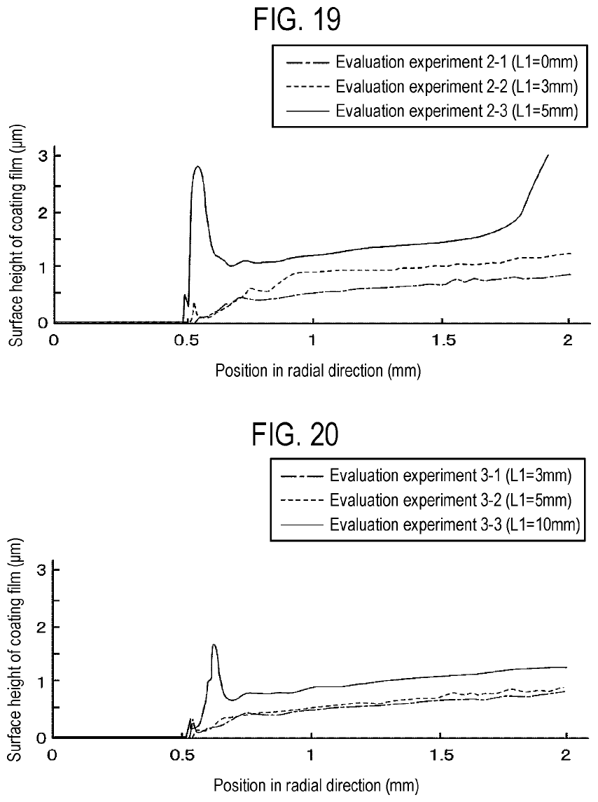

FIG. 18 is a graph diagram illustrating results of Evaluation Experiment 1. In the graph of FIG. 18, results of Evaluation Experiments 1-1, 1-2, 1-3, 1-4, and 1-5 are illustrated by thin solid lines, dotted lines, dash-single-dotted lines, dash-double-dotted lines, and thick solid lines, respectively. The horizontal axis of the graph represents a distance (in mm) from the position of 0 mm toward a peripheral end of the wafer W in the radial direction of the wafer W in a state in which a position separated by a predetermined distance from the center P of the wafer W is set to 0 mm. Hereinafter, this distance will be expressed as a radial position. The vertical axis of the graph represents the height (in μm) of the surface of the coating film M in a state in which the height of the surface of the wafer W on which the coating film M is not formed is set to 0 mm. Since the horizontal and vertical axes of the graph are set in this way, the waveform of the graph indicates the shape of the coating film M in the radial direction of the wafer W. The vertical and horizontal axes of graphs in each figure described after FIG. 19, illustrated in experiments after Evaluation Experiment 2, are set in the same way as the vertical and horizontal axes of the graph in FIG. 18 of Evaluation Experiment 1. Therefore, the shape of the coating film M is represented by the waveform.

The waveform of the graph for Evaluation Experiment 1-1 illustrates a relatively large peak of about 3 μm at a position around 0.5 mm in the radial direction, thereby confirming that the hump M1 could not be eliminated. In Evaluation Experiments 1-2 to 1-5, a peak of a first stage and a peak of a second stage are shown within a range of a position of 0.5 mm to a position slightly larger than 0.5 mm in the radial direction. The peak of the second stage is a peak that appears closer to the peripheral end of the wafer W than the peak of the first stage. It is considered that a peak at each stage indicates a protrusion of a film caused by collapse of the hump M1 as described in FIG. 11. The peak of the first stage and the peak of the second stage in each of Evaluation Experiments 1-2 to 1-5 are smaller than the peak of the waveform in Evaluation Experiment 1-1 and are equal to or less than 1.3 μm. Therefore, in Evaluation Experiments 1-2 to 1-5, it was confirmed that the hump M1 could be removed by discharging air.

From the results of Evaluation Experiments 1-1 to 1-5, it may be appreciated that it is necessary to discharge air to the coating film M before drying progresses in order to eliminate the hump M1. Therefore, it is desirable to start discharging air onto the wafer W before discharging the coating liquid shown in the embodiment in order to more reliably eliminate the hump M1.

When comparing the results of Evaluation Experiments 1-2 to 1-4 with the result of Evaluation Experiment 1-5, Evaluation Experiments 1-2 to 1-4 in which the rotational speed is 100 rpm have a smaller peak of the first stage than Evaluation Experiment 1-5 in which the rotational speed is 250 rpm. As described in the embodiment, this is considered to be because, in Evaluation Experiments 1-2 to 1-4, the drying of the inner peripheral end of the coating film M was suppressed by relatively lowering the rotational speed of the wafer W and thus a pressure effect caused by air was greatly obtained. Therefore, from the above test results, as described in the embodiment, the rotational speed of the wafer W is desirably lower than 250 rpm, more desirably, 100 rpm or less.

When comparing the results of Evaluation Experiments 1-2 to 1-4, the peak of the second stage is smaller in order of Evaluation Experiments 1-4, 1-3, and 1-2. In other words, the larger the flow rate of the air, the smaller the peak of the second stage. Therefore, it may be appreciated that the flow rate of the air is desirably 20 mL/min or more, more desirably, a larger flow rate within this range.

### Evaluation Experiment 2

As in Evaluation Experiment 1, the coating film M was formed on the wafer W using the experiment device and the film thickness of the coating film M was measured. In this Evaluation Experiment 2, the coating film M was formed with the film separation distance L1 described in FIG. 4 and the like, which is set to a different value for each wafer W. For Evaluation Experiments 2-1, 2-2, and 2-3, the film separation distance L1 was set to 0 mm, 3 mm, and 5 mm, respectively. In these Evaluation experiments 2-1 to 2-3, the nozzle height distance H described in FIG. 4 was 5 mm, and the side-view nozzle angle θ was 60 degrees.

The results of Evaluation Experiments 2-1, 2-2, and 2-3 are illustrated in the graph of FIG. 19 by dash-dotted lines, dotted lines, and solid lines, respectively. In Evaluation Experiment 2-3, a relatively large peak of about 3 μm was shown at a position near 0.5 mm in the radial direction. However, in Evaluation Experiments 2-1 and 2-2, such a large peak was not observed. Therefore, although the hump M1 could not be eliminated in Evaluation Experiment 2-3, it was confirmed that the hump M1 could be eliminated in Evaluation Experiments 2-1 and 2-2. From the result of Evaluation Experiment 2, it may be appreciated that the film separation distance L1 is desirably set to a value smaller than 5 mm and more desirably set to 0 mm to 3 mm.

### Evaluation Experiment 3

As in Evaluation Experiment 1, the coating film M was formed on the wafer W using the experiment device and the film thickness of the coating film M was measured. In this Evaluation Experiment 3, the coating film M was formed by setting the nozzle height distance H to a different value for each wafer W. In Evaluation Experiments 3-1, 3-2, and 3-3, the nozzle height distance H was set to 3 mm, 5 mm, and 10 mm, respectively. In these Evaluation Experiments 3-1 to 3-3, the film separation distance L1 described above was set to 0 mm, and the side-view nozzle angle θ was set to 60 degrees.

The results of Evaluation Experiments 3-1, 3-2, and 3-3 are illustrated in the graph of FIG. 20 by dash-dotted lines, dotted lines, and solid lines, respectively. As is apparent from the waveform of the graph, in Evaluation experiment 3-3, a peak of a first stage and a peak of a second stage were seen at a position of around 0.5 mm in the radial direction, and the peak of the second stage was relatively large as 1.5 μm or more. However, such a large peak was not confirmed in Evaluation Experiments 3-1 and 3-2. Therefore, in Evaluation Experiments 3-1 and 3-2, it is considered that the hump M1 was collapsed as described in FIG. 11, and it was confirmed that the height of a protrusion of a film generated by the collapse was also suppressed. Thus, from the result of Evaluation Experiment 3, it may be appreciated that the nozzle height distance H is desirably set to a value smaller than 10 mm and more desirably set to 3 mm to 5 mm.

### Evaluation Experiment 4

As in Evaluation Experiment 1, the coating film M was formed on the wafer W using the experiment device and the film thickness of the coating film M was measured. In this Evaluation Experiment 4, the coating film M was formed by setting the side-view nozzle angle θ to a different value for each wafer W. In Evaluation Experiments 4-1 and 4-2, the side-view nozzle angle θ was set to 60 degrees and 30 degrees, respectively. In these Evaluation Experiments 4-1 to 4-2, the film separation distance L1 described above was 0 mm, and the nozzle height distance H was 3 mm.

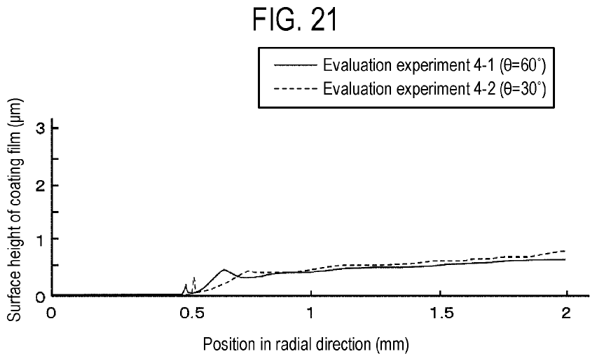

The results of Evaluation Experiments 4-1 and 4-2 are illustrated in the graph of FIG. 21 by solid lines and dotted lines, respectively. As is apparent from the waveform of the graph, the hump M1 was not observed in both Evaluation Experiments 4-1 and 4-2. Thus, it is considered that the hump M1 was eliminated. As described above, the results of Evaluation Experiment 4 showed that it is desirable to set the side-view nozzle angle θ to 30 degrees to 60 degrees in order to eliminate the hump M1.

### Evaluation Experiment 5

As in Evaluation Experiment 1, the coating film M was formed on the wafer W using the experiment device and the film thickness of the coating film M was measured. In this Evaluation Experiment 5, the coating film M was formed by setting the temperature of the air supplied to the gas nozzle 42 to a different value for each wafer W. In Evaluation Experiments 5-1, 5-2, and 5-3, the temperatures were set at 24 degrees C., 20 degrees C., and 16 degrees C., respectively. The temperature of 24 degrees C. is the same as that of a room in which this experiment is conducted. In these Evaluation Experiments 5-1 to 5-3, the above-mentioned film separation distance L1 was set to 0 mm, the nozzle height distance H was set to 3 mm, and the flow rate of discharged air was set to 20 L/min.

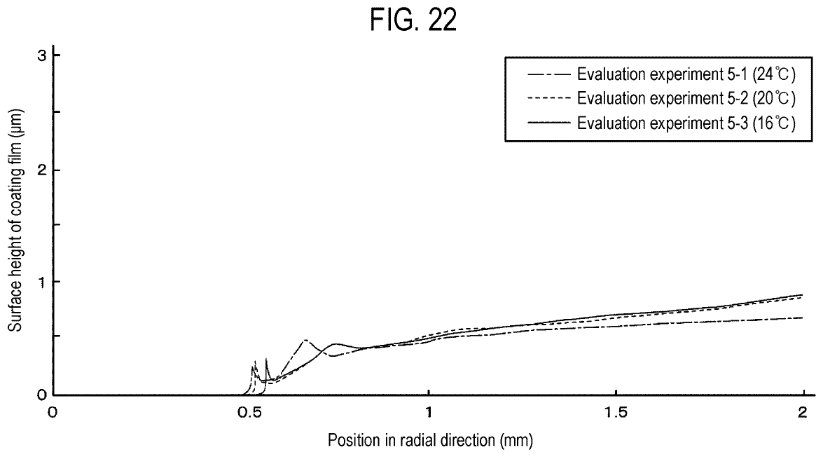

The results of Evaluation Experiments 5-1, 5-2, and 5-3 are illustrated in the graph of FIG. 22 by dash-dotted lines, the dotted lines, and solid lines, respectively. As is apparent from the waveform of the graph, the hump M1 was not observed in any of Evaluation Experiments 5-1 to 5-3. Thus, it is considered that the hump M1 was eliminated. Therefore, it was found that the influence of the temperature of the air in eliminating the hump M1 was small in the range of 16 degrees C. to 24 degrees C. The temperature of 16 degrees C. to 24 degrees C. was desirable as the temperature of the air used.

### Evaluation Experiment 6

As in Evaluation Experiment 1, the coating film M was formed on the wafer W using the experiment device and the film thickness of the coating film M was measured. In this Evaluation Experiment 6, the coating film M was formed by setting the flow rate of discharged air to a different value for each wafer W. In Evaluation Experiments 6-1, 6-2, and 6-3, the flow rates were set to 30 mL/min, 20 mL/min, and 10 mL/min, respectively. In these Evaluation Experiments 6-1 to 6-3, the above-mentioned film separation distance L1 was set to 0 mm, the nozzle height distance H was set to 3 mm, and the temperature of the discharged air was set to 16 degrees C.

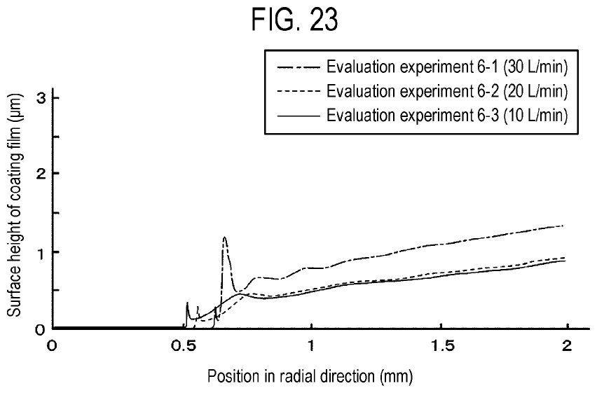

The results of Evaluation Experiments 6-1, 6-2, and 6-3 are illustrated in the graph of FIG. 23 by solid lines, dotted lines, and dash-dotted lines, respectively. As is apparent from the waveform of the graph, in Evaluation Experiment 6-3, a peak of a first stage and a peak of a second stage were observed at a position around 0.5 mm in the radial direction, and the height of the peak of the second stage was relatively large at a level of 1 μm or more. However, such large peaks were not observed in Evaluation Experiments 6-1 and 6-2, and the heights of the peaks were 0.5 μm or less. Therefore, in Evaluation Experiments 3-1 and 3-2, it is considered that the hump M1 collapsed as described in FIG. 11. It was confirmed that the height of a protrusion of a film generated by the collapse was also suppressed. Thus, from the result of Evaluation Experiment 6, it may be appreciated that the flow rate of the discharged air is desirably greater than 10 L/min and, more desirably, 20 L/min.

### EXPLANATION OF REFERENCE NUMERALS

W: Wafer
R1: Projection region
R2: Projection region
41: Coating liquid nozzle
42: Gas nozzle

1. A coating film forming apparatus, comprising:
a rotation holder configured to hold and rotate a substrate;
a coating liquid nozzle configured to discharge a coating liquid to a first position of a peripheral edge portion of the substrate which is rotating and form a coating film of an annular shape along a circumference of the substrate; and
a gas nozzle configured to discharge gas to a second position on a downstream side of a rotational direction of the substrate near a rotational center of the substrate rather than to the first position on the substrate which is rotating, and provided to shape the coating film by a flow of the gas toward a peripheral end of the substrate from the second position.

2. The coating film forming apparatus of claim 1, further comprising: a movement mechanism configured to:
move the coating liquid nozzle between a first processing position, which is above the substrate, at which the coating liquid is discharged to the first position, and a first standby position, which is defined outside the substrate in a plan view; and
move the gas nozzle between a second processing position, which is above the substrate, at which the gas is discharged to the second position, and a second standby position, which is defined outside the substrate in a plan view.

3. The coating film forming apparatus of claim 2, wherein the movement mechanism is common to the coating liquid nozzle and the gas nozzle.

4. The coating film forming apparatus of claim 2, wherein the movement mechanism includes:
a first movement mechanism configured to move the coating liquid nozzle; and
a second movement mechanism configured to move the gas nozzle independently of the coating liquid nozzle.

5. The coating film forming apparatus of claim 2, wherein a height of the gas nozzle relative to a surface of the substrate when the gas is discharged is 1 mm to 5 mm.

6. The coating film forming apparatus of claim 1, wherein the gas nozzle discharges the gas to the second position from a center side of the substrate toward a peripheral end side of the substrate.

7. The coating film forming apparatus of claim 6, wherein an angle between a surface of the substrate and a discharge direction of the gas by the gas nozzle is 60 degrees or less in a side view.

8. The coating film forming apparatus of claim 1, wherein the gas nozzle discharges the gas in a direction that follows the rotational direction of the substrate in a plan view.

9. The coating film forming apparatus of claim 8, wherein an angle between a tangent line drawn with respect to a circle formed by a trajectory of a center of the second position with rotation of the substrate and a discharge direction of the gas by the gas nozzle is 30 degrees to 90 degrees.

10. The coating film forming apparatus of claim 1, wherein a distance between the first position and the second position in the rotational direction of the substrate is 30 mm to 100 mm.

11. The coating film forming apparatus of claim 1, wherein a distance between a center of the second position and an inner peripheral end of the coating film in a discharge direction of the gas in a plan view is 0 mm to 3 mm.

12. The coating film forming apparatus of claim 1, wherein a duration in which the coating liquid is discharged to the first position by the coating liquid nozzle and a duration in which the air is discharged to the second position by the gas nozzle overlap.

13. The coating film forming apparatus of claim 12, wherein the gas nozzle starts to discharge the gas to the second position before the coating liquid nozzle discharges the coating liquid to the first position.

14. The coating film forming apparatus of claim 1, wherein a diameter of a discharge port of the gas nozzle is 0.5 mm to 2 mm.

15. A coating film forming method, comprising:
holding and rotating a substrate by a rotation holder;
discharging, by a coating liquid nozzle, a coating liquid to a first position of a peripheral edge portion of the substrate which is rotating, and forming a coating film of an annular shape along a circumference of the substrate;
discharging, by a gas nozzle, gas to a second position on a downstream side of a rotational direction of the substrate near a rotational center of the substrate rather than to the first position on the substrate which is rotating; and
shaping the coating film by a flow of the gas toward a peripheral end of the substrate from the second position.

16. A non-transitory computer-readable storage medium storing a computer program used in a coating film forming apparatus,
wherein the computer program incorporates a group of steps for executing the coating film forming method of claim 15.
